(19) United States
(12) Patent Application Publication
(10) Pub. No.: US 2026/0157144 A1
(43) Pub. Date: Jun. 4, 2026

(54) OVERLAY METROLOGY TARGET

(71) Applicant: KLA Corporation, Milpitas, CA (US)

(72) Inventors: Roie Volkovich, Hadera (IL); Avner Safrani, Misgav (IL); Eitan Hajaj, Ashqelon (IL); Ohad Bachar, Timrat (IL); DongSub Choi, Yongin City (KR); Kang-san Lee, Yongin (KR)

(21) Appl. No.: 19/064,208

(22) Filed: Feb. 26, 2025

Related U.S. Application Data
(60) Provisional application No. 63/726,691, filed on Dec. 2, 2024.

(51) Int. Cl. H01L 21/68; G01B 11/27; H01L 23/544

(52) U.S. Cl. CPC H10P 72/53; G01B 11/272; H10W 46/00; H10W 46/301

(57) ABSTRACT

An overlay target may include a first bonded substrate arranged on a first layer. The overlay target may include a second bonded substrate arranged on a second layer. The overlay target may include a third bonded substrate arranged on a third layer, where each bonded substrate includes one or more features embedded in the respective bonded substrate.

### CROSS-REFERENCE TO RELATED APPLICATIONS

The present disclosure claims the benefit of U.S. Provisional Patent Application No. 63/726,691, filed Dec. 2, 2024, which is herein incorporated by reference in the entirety.

### TECHNICAL FIELD

The present invention relates generally to overlay metrology and, more particularly, to measuring overlay on stacked wafers and stacked dies.

### BACKGROUND

In semiconductor manufacturing, precise alignment of wafers and dies is crucial for ensuring high yield and performance. Traditional overlay measurement targets are limited to two layers, which is insufficient for advanced packaging processes involving multiple stacked layers. As the industry moves towards 3D heterogeneous integration, there is a need for improved metrology techniques that can handle the complexity of multiple stacked layers. For example, with 3D heterogenous integration, manufacturers are able to stack and integrate more silicon devices in a single package, increasing the transistor density and product performance.

Further, key process development activity is occurring in the wafer-to-wafer (W2W) and die-to-wafer (D2W) bonding processes to reduce interconnect pitches to small values (e.g., sub-micrometer levels). As such, precise control of bond pad alignment is needed to ensure the pads (e.g., copper pads) line up properly before being bonded, thus increasing the need for overlay metrology precision and die-bonder control.

There is therefore a need to develop systems and methods to address the above deficiencies.

### SUMMARY

An overlay metrology target is disclosed, in accordance with one or more embodiments of the present disclosure. In embodiments, the overlay metrology target includes a first bonded substrate arranged on a first layer. In embodiments, the overlay metrology target includes a second bonded substrate arranged on a second layer. In embodiments, the overlay metrology target includes a third bonded substrate arranged on a third layer. In embodiments, each bonded substrate includes one or more features embedded in the respective bonded substrate.

A metrology system is disclosed, in accordance with one or more embodiments of the present disclosure. In embodiments, the metrology system includes a light source configured to provide illumination. In embodiments, the metrology system includes a single objective lens configured to direct the illumination to an overlay target on a sample and collect sample light from the overlay target, where the sample includes an overlay target, where the overlay target includes first bonded substrate arranged on a first layer, a second bonded substrate arranged on a second layer, and a third bonded substrate arranged on a third layer, where each bonded substrate includes one or more features embedded in the respective bonded substrate. In embodiments, the metrology system includes a detector configured to image the sample based on the sample light, where each feature of the one or more features of the overlay target are within a field of view of the detector. In embodiments, the metrology system includes a controller including one or more processors configured to execute program instructions causing the one or more processors to implement a metrology recipe by: receiving an image of the overlay target based on the metrology recipe; and generating an overlay measurement based on the image.

A metrology method is disclosed, in accordance with one or more embodiments of the present disclosure. In embodiments, the metrology method includes illuminating an overlay target on a sample with an objective lens with an illumination, where the sample includes an overlay target, where the overlay target includes first bonded substrate arranged on a first layer, a second bonded substrate arranged on a second layer, and a third bonded substrate arranged on a third layer, where each bonded substrate includes one or more features embedded in the respective bonded substrate. In embodiments, the metrology method includes generating an image of the overlay target with a detector. In embodiments, the metrology method includes generating an overlay measurement based on the image.

It is to be understood that both the foregoing general description and the following detailed description are exemplary and explanatory only and are not necessarily restrictive of the invention as claimed. The accompanying drawings, which are incorporated in and constitute a part of the specification, illustrate embodiments of the invention and together with the general description, serve to explain the principles of the invention.

### BRIEF DESCRIPTION OF DRAWINGS

The numerous advantages of the disclosure may be better understood by those skilled in the art by reference to the accompanying figures.

FIG. 1 illustrates a block diagram of an overlay metrology system, in accordance with one or more embodiments of the present disclosure.

FIG. 2A illustrates a conceptual side view of an overlay target, in accordance with one or more embodiments of the present disclosure.

FIG. 2B illustrates a conceptual top view of an overlay target, in accordance with one or more embodiments of the present disclosure.

FIG. 2C illustrates a conceptual top view of an overlay target, in accordance with one or more embodiments of the present disclosure.

FIG. 2D illustrates a conceptual top view of an overlay target, in accordance with one or more embodiments of the present disclosure.

FIG. 3A illustrates a conceptual side view of an overlay target, in accordance with one or more embodiments of the present disclosure.

FIG. 3B illustrates a conceptual top view of an overlay target, in accordance with one or more embodiments of the present disclosure.

FIG. 4 illustrates a conceptual top view of an overlay target, in accordance with one or more embodiments of the present disclosure.

FIG. 5 illustrates a conceptual top view of an inner substrate and outer substrate of an overlay target used to determine overlay, in accordance with one or more embodiments of the present disclosure.

FIG. 6A illustrates a conceptual top view of a frame target of an overlay target used to determine overlay, in accordance with one or more embodiments of the present disclosure.

FIG. 6B illustrates a plot depicting determining accumulated overlay error from a stacked sample using the frame target depicted in FIG. 6A, in accordance with one or more embodiments of the present disclosure.

FIG. 7 illustrates a conceptual view of a configuration of the overlay metrology system including a single detector, in accordance with one or more embodiments of the present disclosure.

FIG. 8 is a flow diagram illustrating steps performed in an overlay metrology method, in accordance with one or more embodiments of the present disclosure.

### DETAILED DESCRIPTION

Reference will now be made in detail to the subject matter disclosed, which is illustrated in the accompanying drawings. The present disclosure has been particularly shown and described with respect to certain embodiments and specific features thereof. The embodiments set forth herein are taken to be illustrative rather than limiting. It should be readily apparent to those of ordinary skill in the art that various changes and modifications in form and detail may be made without departing from the spirit and scope of the disclosure.

Embodiments of the present disclosure are directed to systems and methods for providing sample overlay measurements of overlay targets of a stacked sample. For example, the stacked sample may include two or more stacked substrates such as, but not limited to, a die-to-wafer (D2W) sample, a wafer-to-wafer (W2W) sample, or a die-to-die (D2D) sample. In cases where the stacked sample includes the W2W sample, the overlay between the different bonded wafers may be determined in a single shot. For example, in a non-limiting example, in one overlay measurement, the overlay between wafer 1, wafer 2, and wafer n can be measured and reported. Thus, saving time and improving alignment accuracy during each step of the stacking process. Additional embodiments of the present disclosure are directed towards using frame targets, where each frame may be printed in each substrate. For example, frame targets (e.g., boxes filled with metal) may be printed in each die/wafer using a lithography tool.

Further, embodiments of the present disclosure are directed to determining overlay by allocating the center of symmetry (CoS) of an overlay target and calculating a vector between the CoS. For example, for each wafer (or die), the CoS may be calculated, where the vector of each CoS is compared to determine overlay of the sample. In embodiments, the measured overlay may be used to correct bonder alignment. For example, the measured overlay may be used as a correctable through feedback and/or feed forward data. In some cases, an accumulated overlay error may be calculated by measuring an offset between the respective CoSs of the respective substrates.

In addition, embodiments of the present disclosure are directed to using dedicated hardware to measure overlay using the overlay targets of the stacked sample. For example, the dedicated hardware may include a detector (e.g., camera) with a large field of view (FOV) and/or flexible numerical aperture (NA) with large depth of focus. In embodiments, a Site by Site (SBS) targets can be measured using the dedicated hardware. The dedicated hardware may image the stacked sample using dark field technology, such that the performance of such targets is improved by reducing the noise bright field measurements introduce. It is contemplated herein that adjusting the NA and/or using double-grab imaging may enable measuring overlay between the top substrates (e.g., wafers/dies) only without measuring the signal from the bottom substrates (e.g., wafers/dies).

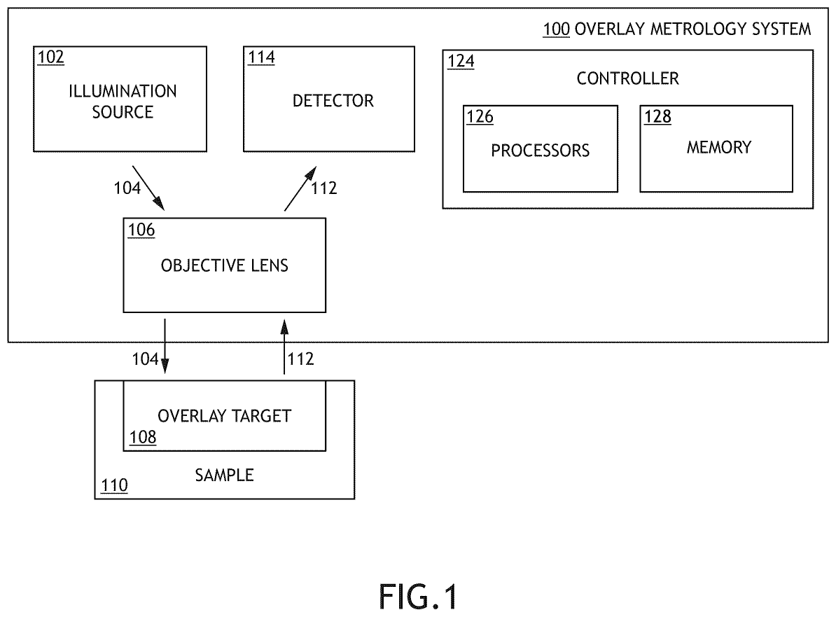

Referring now to FIGS. 1-8, systems and methods providing imaging overlay targets of bonded samples for overlay metrology are now described in greater detail, in accordance with one or more embodiments of the present disclosure.

FIG. 1 illustrates a block diagram of an overlay metrology system 100, in accordance with one or more embodiments of the present disclosure.

In embodiments, the overlay metrology system 100 includes an illumination source 102 configured to generate illumination 104, a single objective lens 106 to direct the illumination to an overlay target 108 on a sample 110 and collect light (e.g., sample light 112) from the overlay target 108, and one or more detectors 114 to generate one or more images of the overlay target 108 based on the collected sample light 112.

An overlay metrology system is generally described in U.S. patent application Ser. No. 18/999,649 filed on Dec. 23, 2024, which is herein incorporated by reference in its entirety.

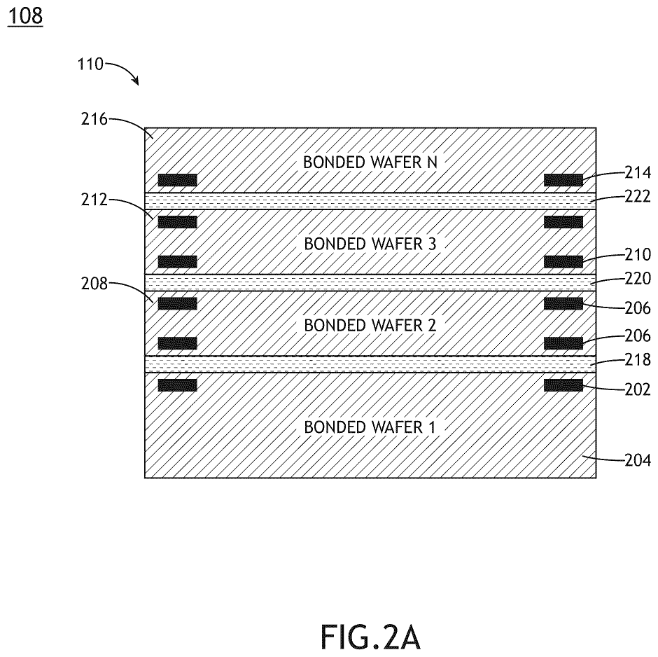

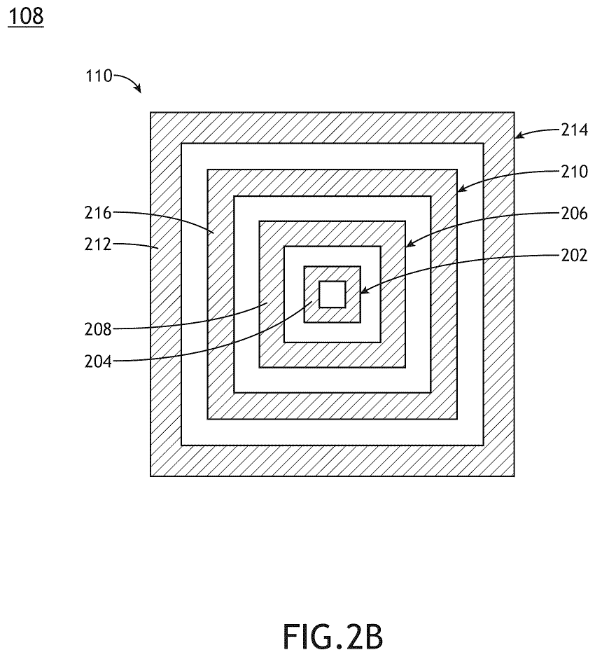

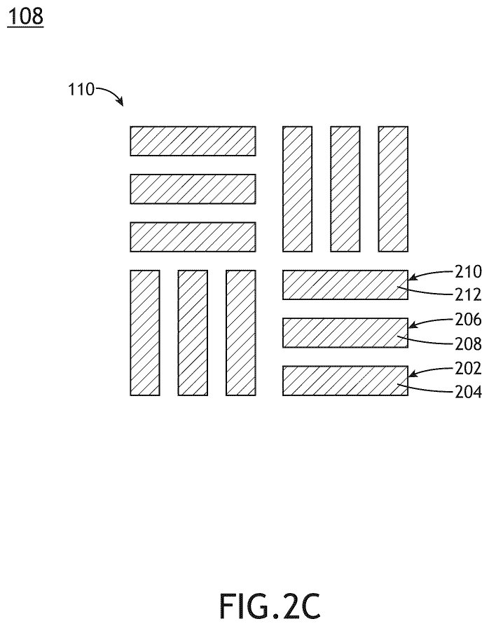

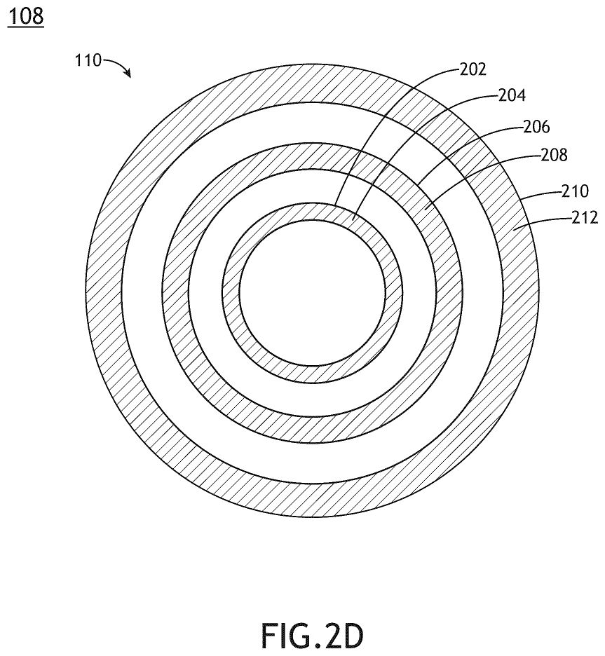

FIGS. 2A-4 illustrate conceptual views of an overlay target 108, in accordance with one or more embodiments of the present disclosure.

In embodiments, an overlay target 108 includes a plurality of substrates. Each substrate may include one or more features. The features of the plurality of substrates may generally be at any depth in the respective substrates. In embodiments, the features may be embedded within a respective substrate. For example, the features may be located at or near the respective bonding interface or buried further within the respective substrate. In embodiments, the overlay target 108 includes an image-based overlay target for use with an image-based metrology system.

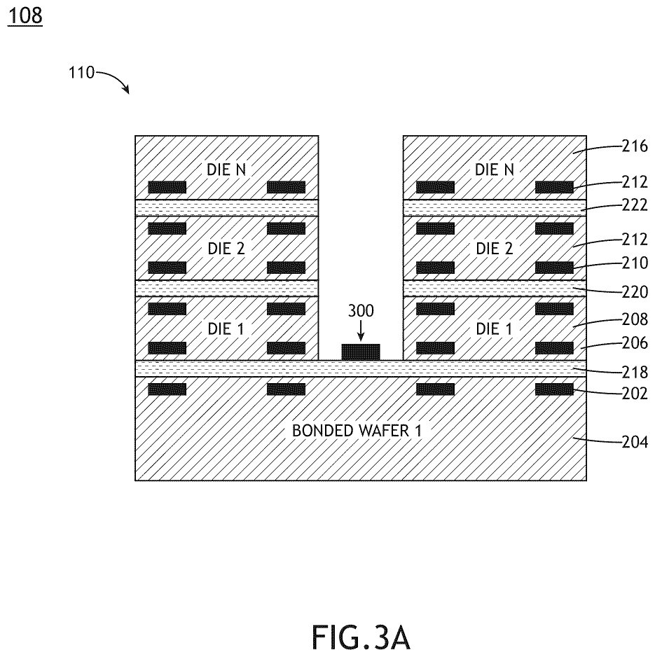

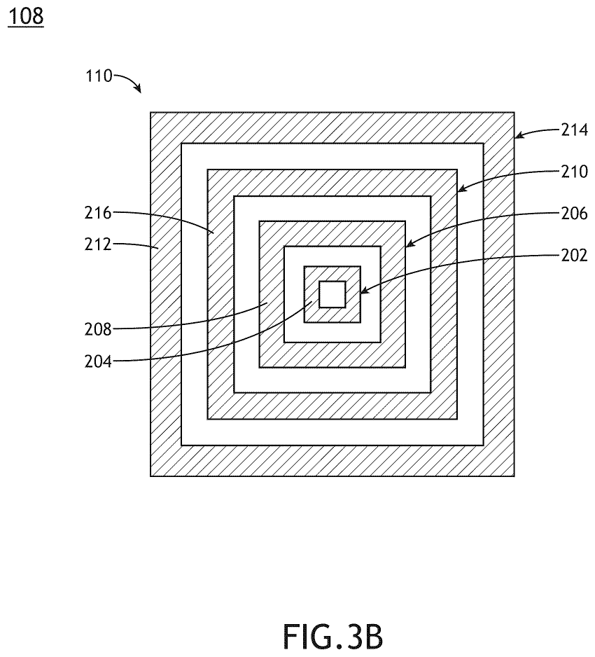

The plurality of substrates may be any type of substrate that may be bonded to create a bonded sample 110. For example, as shown in FIGS. 2A-2D, the sample 110 may be a W2W sample where the plurality of substrates each correspond to wafers. It is contemplated herein that the respective wafers may have varying thicknesses. By way of another example, as shown in FIGS. 3A-3B, the sample 110 may be a D2W sample where at least one substrate of the plurality of substrates corresponds to a wafer and additional substrate(s) of the plurality of substrates correspond(s) to die(s). It is contemplated herein that the respective wafers/dies may have varying thicknesses. By way of another example, the sample 110 may a D2D sample where the plurality of substrates each correspond to dies.

It is contemplated herein that the overlay target 108 may have any symmetrical shape. For example, as shown in FIGS. 2B and 3B, the overlay target 108 may include a Box-in-Box (BiB) target where the respective substrates are square (or rectangular). For instance, as shown in FIG. 2A, the respective wafers may be square and be of varying sizes, such that the W2W sample (or D2W/D2D), when viewed from the side, appears like a pyramid. By way of another example, as shown in FIG. 2C, the overlay target 108 may include an advanced image metrology (AiM) target. By way of another example, as shown in FIG. 2D, the overlay target 108 may include a Circle-in-Circle (CiC) target, where the respective substrates are circular. For instance, as shown in FIG. 2D, the respective wafers may be circular and be of varying sizes, such that the W2W sample, when viewed from the side, appears like a circular shaped pyramid.

Referring generally to FIGS. 2A-2D, in embodiments, the sample 110 includes a W2W sample. In a non-limiting example, as shown in FIGS. 2A-2B, the overlay target 108 includes first substrate features 202 on a first substrate 204 (e.g., a bottom substrate) forming a sample 110, second substrate features 206 on a second substrate 208 forming a sample 110, third substrate features 210 on a third substrate 212 forming a sample 110, up to N substrate features 214 on a N substrate 216 (e.g., a top substrate) forming a sample 110, where the first substrate 204 and the second substrate 208 are bonded at a first interface 218, the second substrate 208 and the third substrate 212 are bonded at a second interface 220, and the third substrate 212 and the N substrate 216 are bonded at a third interface 222. For instance, the first substrate 204 may correspond to a first bonded wafer, the second substrate 208 may correspond to a second bonded wafer, and the third substrate 210 may correspond to a third bonded wafer, where the respective bonded wafers may be stacked on top of one another to form the stacked W2W sample. In this regard, overlay (e.g., W2W) may be determined between the respective bonded wafers 204, 206, 212, 216.

In a non-limiting example, as shown in FIGS. 2C-2D, the overlay target 108 includes first substrate features 202 on a first substrate 204 (e.g., a bottom substrate) forming a sample 110, second substrate features 206 on a second substrate 208 forming a sample 110, and third substrate features 210 on a third substrate 212 forming a sample 110, where the first substrate 204 and the second substrate 208 are bonded at a first interface 218 and the second substrate 208 and the third substrate 212 are bonded at a second interface 220. For instance, the first substrate 204 may correspond to a first bonded wafer, the second substrate 208 may correspond to a second bonded wafer, and the third substrate 210 may correspond to a third bonded wafer, where the respective bonded wafers may be stacked on top of one another to form the stacked W2W sample.

Referring generally to FIGS. 3A-3B, in embodiments, the sample 110 includes a D2W sample. In a non-limiting example, as shown in FIGS. 3A-3B, the overlay target 108 includes first substrate features 202 on a first substrate 204 (e.g., a bottom substrate) forming a sample 110, second substrate features 206 on a second substrate 208 forming a sample 110, third substrate features 210 on a third substrate 212 forming a sample 110, up to N substrate features 214 on a N substrate 216 (e.g., a top substrate) forming a sample 110, where the first substrate 204 and the second substrate 208 are bonded at a first interface 218, the second substrate 208 and the third substrate 212 are bonded at a second interface 220, and the third substrate 212 and the N substrate 216 are bonded at a third interface 222. For instance, the first substrate 204 may correspond to a bonded wafer, the second substrates 208 may correspond to first dies, and the third substrate 210 may correspond to second dies, where the respective bonded dies may be stacked on top of one another and stacked on the bonded wafer to form the stacked D2W sample. In this regard, overlay (e.g., D2W) may be determined between the bonded wafer 204 and one or more of the respective dies 206, 212, 216. Further, overlay (e.g., D2D overlay) may be determined between the respective dies 206, 212, 216.

In embodiments, the overlay target 108 includes a Side-By-Side (SBS) target 300. For example, as shown in FIG. 3A, the SBS target 300 may be laterally displaced on the sample, such that the SBS target 300 may be bonded to the bonded wafer 204 and arranged adjacent the die 208. It is contemplated herein that the SBS target 400 configuration shown in FIG. 3A is provided merely for illustrative purposes and shall not be construed as limiting the scope of the present disclosure.

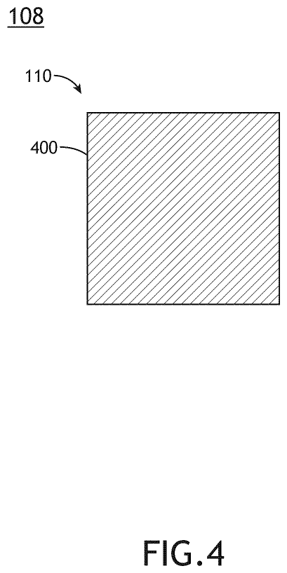

In embodiments, the overlay target 108 includes a frame target 400. For example, as shown in FIG. 4, the frame target 400 may include a box filled with a predetermined material (e.g., metal, or the like). The frame target 400 may be printed in each substrate. For example, the frame target 400 may be printed in each die using a lithography tool.

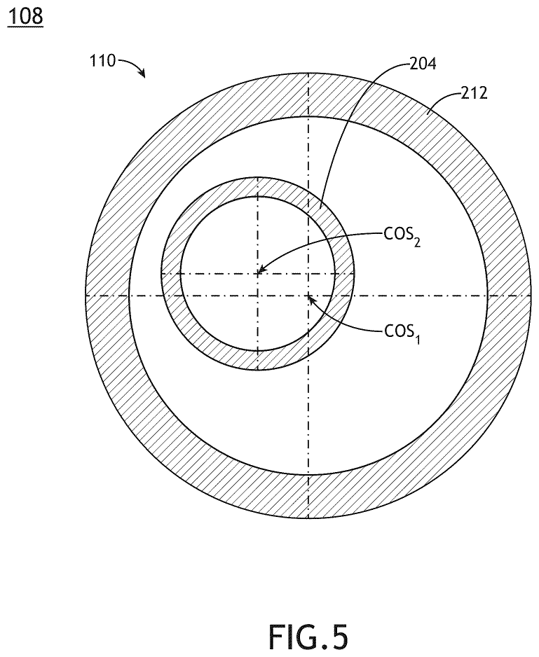

FIG. 5 illustrates a conceptual top view of an inner substrate and outer substrate of an overlay target 108 used to determine overlay, in accordance with one or more embodiments of the present disclosure.

In embodiments, the Center of Symmetry (CoS) for a respective substrate may be calculated and compared with an additional substrate to determine overlay. For example, as shown in FIG. 5, a first CoS₁ for an outer substrate (or bottom substrate) may be determined and a second CoS₂ for an inner substrate (or top substrate) may be determined. In this regard, the first CoS₁ for the outer substrate (or bottom substrate) and the second CoS₂ for the inner substrate (or top substrate) may be compared to determine the respective overlay between the substrates. Where the outer substrate (or bottom substrate) is a bonded wafer and the inner substrate (or top substrate) is a bonded wafer, W2W overlay may be determined between the respective bonded wafers. Where the outer substrate (or bottom substrate) is a bonded wafer and the inner substrate (or top substrate) is a bonded die, D2W overlay may be determined between the respective bonded wafer and bonded die. Where the outer substrate (or bottom substrate) is a bonded die and the inner substrate (or top substrate) is a bonded die, D2D overlay may be determined between the respective bonded dies.

It is contemplated herein that although the CoS for only the inner and outer substrates is shown, the CoS for any respective substrate (wafer/die) may be used to determine overlay between respective substrates. As such, FIG. 5 shall not be construed as limiting the scope of the present disclosure.

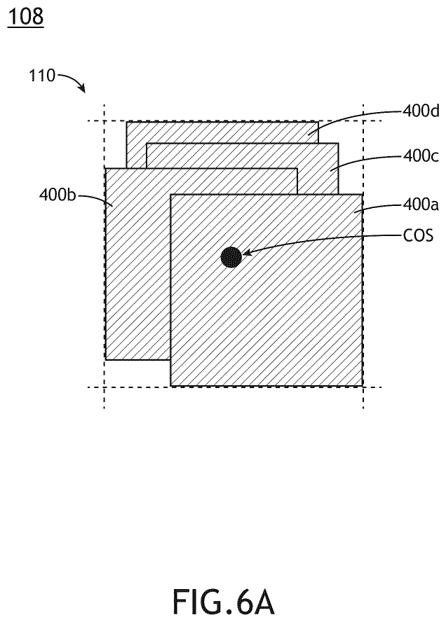

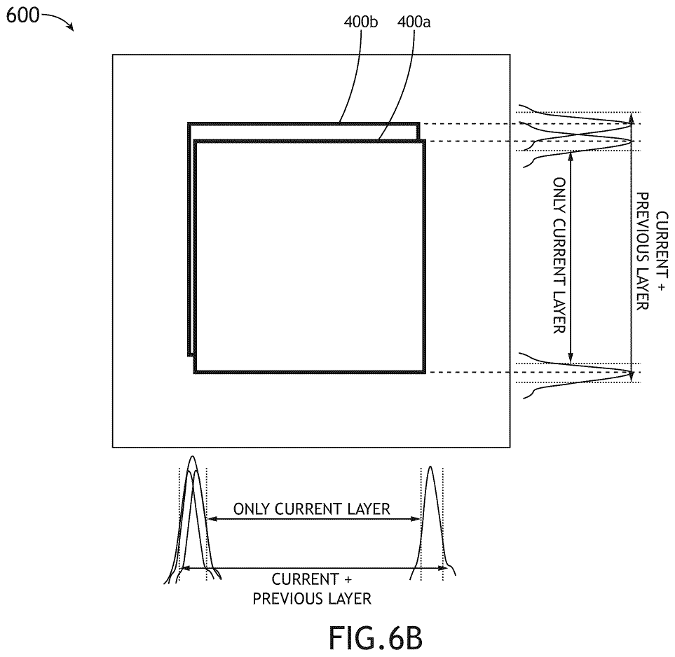

FIG. 6A illustrates a conceptual top view of a frame target 400 of an overlay target 108 used to determine overlay using brightfield measurement, in accordance with one or more embodiments of the present disclosure. FIG. 6B illustrates a plot 600 depicting determining accumulated overlay error from a stacked sample using a frame target 400 and darkfield measurement, in accordance with one or more embodiments of the present disclosure.

In embodiments, overlay may be determined using a plurality of frame targets 400. For example, as shown in FIG. 6A, the overlay target 108 may include at least a first frame target 400a, a second frame target 400b, a third frame target 400c, and a fourth frame target 400d. In this non-limiting example, a brightfield image of the overlay target 108 may be used to calculate overlay. For instance, an offset between the center of symmetry (COS) of the first frame target 400a, the second frame target 400b, the third frame target 400c, and the fourth frame target 400d may be calculated.

In embodiments, accumulated overlay may be determined using the plurality of frame targets 400. For example, as shown in FIG. 6B, a center of mass (COM) may be calculated based on a darkfield image of the overlay target 108. For instance, as shown in FIG. 6B, when measuring in darkfield, the edges of the frame target 400 may be illuminated. In this regard, the edge position may be determined based on the maximum of the derivative of the signal. The inner most edges may correspond to the top substrate 400a (or current layer) and the outer most edges may be a combination of the bottom substrate 400b (or previous layer) layer and the current feature. Thus, the CoM of the inner substrate may correspond to the position of the current layer and the CoM of the outer substrate may be an average position of the previous and current layer. As such, the overlay can be extracted from the respective CoMs, as shown and described below:

$$overlay = {CoM}_{Current} - {CoM}_{Previous} = 2 ( {CoM}_{Inner} - {CoM}_{Outer} ) = 2 ( {CoM}_{Current} - \frac{{CoM}_{Current} + {CoM}_{Previous}}{2} )$$

It is contemplated herein that calculating overlay using the frame targets 400 may reduce the need for calibration marks of any kind.

Referring again to FIG. 1, the overlay metrology system 100 may provide adjustable control of an angular distribution of the illumination 104 directed to the overlay target 108 and/or the collected sample light 112 used to generate an image. In this way, properties such as, but not limited to, an illumination numerical aperture (NA) and/or an imaging NA may be tailored for a measurement of a particular overlay target 108. For example, the overlay metrology system 100 may include an illumination channel 116 with optical elements configured to manipulate the illumination 104 directed to the overlay target 108 such as, but not limited to, an adjustable illumination aperture stop 118 to control an imaging NA or an angular distribution of the illumination 104 more generally. As another example, the overlay metrology system 100 may include at least one collection channel 120 with optical elements configured to manipulate the sample light 112 used for imaging such as, but not limited to, an adjustable collection aperture stop 122 to control an imaging NA or an angular distribution of the sample light 112 more generally.

In embodiments, the metrology system 100 includes a controller 124 including one or more processors 126 configured to execute program instructions stored in memory 128 (e.g., a memory device). The processors 126 of the controller 124 may then execute program instructions causing the processors 126 to implement any of the various steps described in the present disclosure either directly or indirectly (e.g., by generating control signals to control components of the overlay metrology system 100 and/or external components). For example, the processors 126 of the controller 124 may receive one or more images from the detector 114. As another example, the processors 126 of the controller 124 may generate one or more overlay metrology measurements of the sample 110 based on the images. As another example, the processors 126 of the controller 124 may generate correctables to control, based on the overlay metrology measurements, one or more process tools such as, but not limited to, a lithography tool, an etching tool, or a polishing tool. Correctables may be generated to control one or more process tools in any combination of a feedback control loop or a feed-forward control loop. As an illustration, feedback correctables generated in response to metrology measurements on a sample 110 may control a process tool during the fabrication of additional samples in the same or different lots (e.g., in response to drifts of the process tools). As another illustration, feed-forward correctables generated in response metrology measurements on a sample 110 may be used to control a process tool during fabrication of additional features on the sample 110 in future process steps.

Further, the metrology system 100 may be configurable to generate metrology measurements (e.g., overlay measurements) based on any number of metrology recipes, where a metrology recipe may define various imaging parameters used to generate measurement data and/or processing techniques to generate metrology measurements from measurement data. For example, a metrology recipe may include parameters associated with the illumination 104 such as, but not limited to, incidence angles (e.g., azimuth and/or polar incidence angles), polarization, phase characteristics, or wavelength. As another example, a metrology recipe may include parameters associated with sample light 112 used to generate an image such as, but not limited to, collection angles (e.g., for imaging, where different configurations provide different darkfield and brightfield imaging modes), polarization, phase characteristics, or wavelength. As another example, a metrology recipe may include sampling characteristics such as, but not limited to, locations on a sample 110 to be measured (e.g., locations of overlay targets 108) or focus characteristics. As another example, a metrology recipe may include a measurement mode such as a single grab with single detector 114, a double grab with single detector 114, a single grab with dual detectors 114, or a double grab with dual detectors 114. As another example, the metrology recipe may include the nominal position of an objective lens 106 relative to the sample 110 (e.g., a distance between the objective lens and a top surface of the top substrate 204) at any one of the described measurement modes (e.g., working distances associated with any of the measurement modes).

The overlay metrology system 100 may further include a focusing sub-system 130 to monitor and/or provide data for controlling a position of the sample 110 relative to the objective lens 106 (e.g., a focal distance). The focusing sub-system 130 may include any components or combination of components suitable for monitoring and/or providing data associated with a position of the sample 110 such as, but not limited to, a Linnik interferometer. The configuration of the overlay metrology system 100 may be implemented by mounting at least the illumination channel 116, the objective lens 106, and the focusing sub-system 130 on a translation stage 172 (e.g., a high-stiffness translation stage). Such a configuration may provide rapid focusing and selection of an imaging plane. Alternatively, the entire optical system may be mounted on a translation stage.

In embodiments, the overlay metrology system 100 is configured to provide simultaneous imaging of the plurality of substrates on a single detector 114. It is contemplated herein that simultaneous imaging of the plurality of substrates may thus be achieved by controlling an imaging NA to provide that the respective substrate falls within a respective depth of field.

In a general sense, the overlay metrology system 100 may generate images in any imaging configuration including, but not limited to, darkfield imaging or brightfield imaging. However, it is contemplated herein that darkfield imaging may facilitate higher-contrast imaging than brightfield imaging. Further, it is contemplated herein that using darkfield imaging can improve the performance of such targets by reducing the noise bright field measurements introduce.

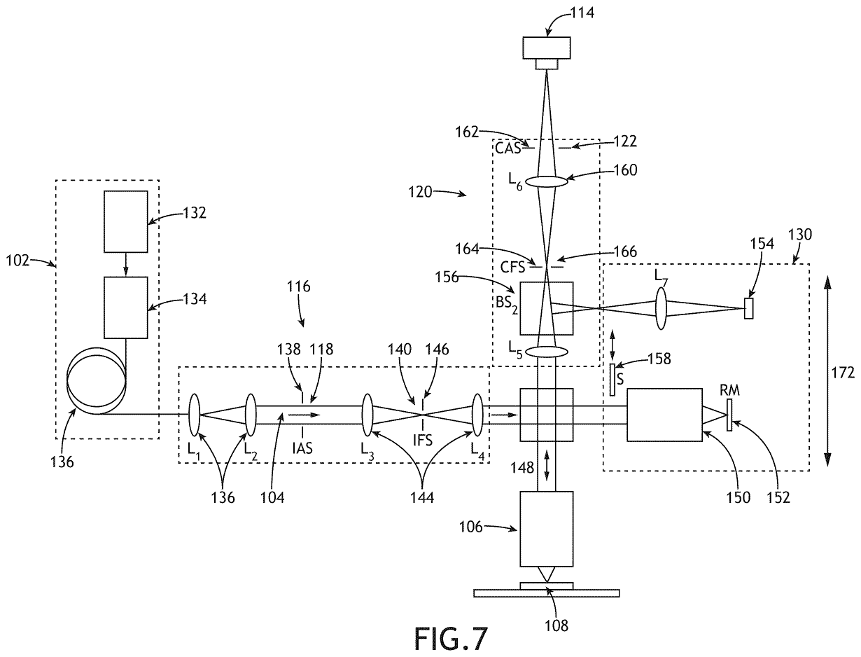

FIG. 7 illustrates a conceptual view of a configuration of the overlay metrology system 100 including a single detector 114, in accordance with one or more embodiments of the present disclosure.

The illumination source 102 may provide illumination 104 with any wavelength suitable for imaging through the top substrate 204. For example, the illumination source 102 may provide illumination 104 having short-wave infrared (SWIR) wavelengths, which may be suitable for imaging through semiconductor substrates such as, but not limited to, silicon substrates. Further, the illumination 104 may have any bandwidth and may be characterized as narrowband or broadband light. In embodiments, the illumination source 102 provides illumination 104 with a tunable spectrum, either directly or through spectral filters. For example, FIG. 7 depicts an illumination source 102 with a light source 132 and one or more spectral filters 134 for spectral selection.

The illumination source 102 may include any light source suitable for providing illumination 104 with the selected wavelengths. For example, the illumination source 102 may include one or more laser sources, one or more light emitting diode (LED) sources, or one or more lamp sources.

The illumination source 102 may provide the illumination 104 using any technique including, but not limited to, fiber optics or free-space optics. For example, FIG. 7 depicts a configuration in which the illumination 104 is provided by fiber optics 136, 144. The illumination channel 116 may utilize any type of fiber optics known in the art. In embodiments, the illumination channel 116 utilizes a multi-mode fiber such as, but not limited to, a square, hexagonal or octagonal core fiber to provide a spatially uniform source of illumination 104.

The illumination channel 116 may include any combination of lenses or other optical elements suitable for directing the illumination 104 to the sample 110 through the objective lens 106. Further, the illumination channel 116 may include relay lenses to provide access to an illumination pupil plane 138 and/or an illumination field plane 140.

Various stops 118, 146 may be placed in the illumination pupil plane 138 and/or the illumination field plane 140 to manipulate the illumination 104 directed to the sample 110. The adjustable illumination aperture stop 118 may include any components suitable for providing adjustable control over the angular profile of the illumination 104. The adjustable illumination aperture stop 118 may provide any angular profile suitable for any imaging technique.

In embodiments, the overlay metrology system 100 includes a beamsplitter 148 or other component suitable for providing simultaneous illumination and collection with the objective lens 106. For example, the beamsplitter 148 directs illumination 104 from the illumination channel 116 to the sample 110 and directs collected sample light 112 to the collection channel 120.

The focusing sub-system 130 may include an additional objective lens 150 that is complementary to the objective lens 106 and a reflecting mirror 152. The focusing sub-system 130 further includes a focusing detector 154 arranged to capture interference between the sample light 112 and a portion of the illumination 104 reflected by the reflecting mirror 152 and picked off by an additional beamsplitter 156. Any suitable focusing detector 154 may be used such as, but not limited to, a photodiode, a spectrometer, or the like. Linnik interferometry is generally described in U.S. Patent Publication 2024/0035810 published on Feb. 1, 2024; U.S. Pat. No. 12,001,148 issued on Jun. 4, 2024; U.S. Pat. No. 11,713,959 issued on Aug. 1, 2023; U.S. Pat. No. 12,066,322 issued on Aug. 20, 2024; and U.S. Pat. No. 11,629,952 issued on Apr. 18, 2023; all of which are incorporated herein by reference in their entirety. The overlay metrology system 100 may include a shutter 158 or adjustable blocker to selectively block a light path to the additional objective lens 150 when the focusing sub-system 130 is not in use to prevent interference during a measurement.

In a manner similar to the illumination channel 116, the collection channel 120 may include any combination of lenses or other optical elements suitable for directing the sample light 112 to one or more detectors 114. For example, FIG. 7 illustrates a collection channel 120 with relay lenses 160 to provide access to a collection pupil plane 162 and/or a collection field plane 164.

Various stops 122, 166 may be placed in the collection pupil plane 162 and/or a collection field plane 164 to manipulate the sample light 112. The adjustable collection aperture stop 122 may include any components suitable for providing adjustable control over the angular profile of sample light 112 such as, but not limited to, one or more apertures on a translation stage or an adjustable spatial light modulator. Further, the adjustable collection aperture stop 122 may provide various shapes to control the imaging NA.

The overlay metrology system 100 may provide any type of darkfield imaging configuration. For example, there may be two darkfield imaging modes: direct darkfield and reverse darkfield. In reverse darkfield, the overlay metrology system 100 may include an annular ring at the adjustable illumination aperture stop 118 and provide a circular aperture at the adjustable collection aperture stop 122 having an opening diameter slightly smaller than the inner diameter of the ring in the adjustable illumination aperture stop 118. In direct darkfield, the adjustable illumination aperture stop 118 may include a circular aperture and the adjustable collection aperture stop 122 may include an annular ring having its smallest diameter slightly larger than the diameter of the adjustable illumination aperture stop 118.

The overlay metrology system 100 may include any number of detectors 114 to provide any number of simultaneous images. For example, FIG. 7 depicts a configuration with a single detector 114, which may be suitable for single-grab imaging or sequential double-grab imaging. As another example, the overlay metrology system 100 may include a configuration with two detectors 114 and associated channel splitting optics (e.g., one or more beamsplitters, or the like), which may be suitable for simultaneous or sequential double-grab imaging. The one or more detectors 114 may incorporate any sensor suitable for collecting the sample light 112. For example, a detector 114 may include, but is not limited to, a charge-coupled device (CCD), a complementary metal-oxide-semiconductor (CMOS) device, or a photodiode array. Further, the sensor may be formed from any suitable material. As an illustration a SWIR sensor suitable for SWIR illumination 104 may be formed from materials such as, but not limited to, InGaAs, PbS, PbSe, or InAsSb.

It is contemplated herein that by adjusting the NA and/or using double-grab imaging can enable measuring overlay between the top substrates (e.g., dies or wafers) only without measuring the signal from the bottom substrates (e.g., dies or wafers).

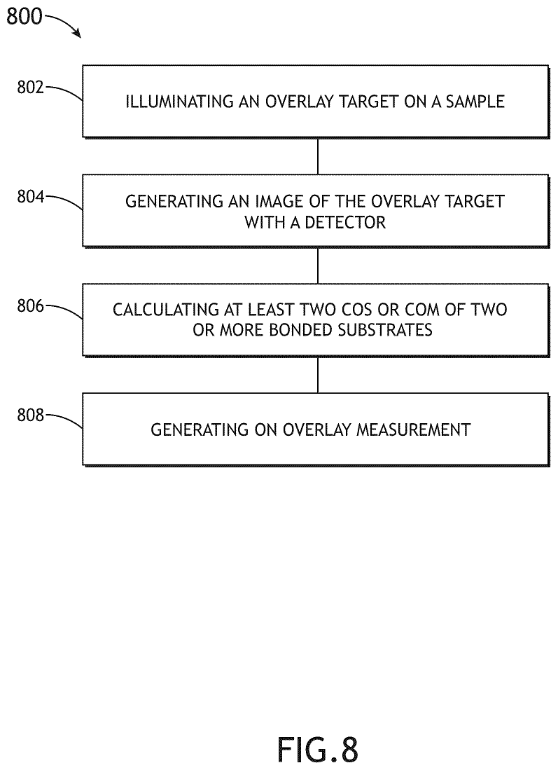

FIG. 8 is a flow diagram illustrating steps performed in an overlay metrology method 800, in accordance with one or more embodiments of the present disclosure. The embodiments and enabling technologies described previously herein in the context of the overlay metrology system 100 should be interpreted to extend to the method 800. For example, the controller 124 may implement one or more steps of the method 800 either directly (e.g., as algorithmic steps) or indirectly by generating control signals that control additional components of the overlay metrology system 100 and/or external components. However, the method 800 is not limited to the architecture of the overlay metrology system 100.

The method 800 may include a step 802 of illuminating the overlay target on the sample with the illumination source.

The method 800 may include a step 804 of generating an image of the overlay target with the detector. In one instance, the image may be a darkfield image. In another instance, the image may be a brightfield image.

The method 800 may include a step 806 of calculating one of at least two center of symmetries (CoS) or two center of masses (COM) of two or more bonded substrates based on the image.

For example, a first CoS₁ for an outer substrate (or bottom substrate) may be determined and a second CoS₂ for an inner substrate (or top substrate) may be determined, where CoS₁ and CoS₂ may be compared to determine the respective overlay.

By way of another example, as shown in FIG. 6B, when measuring in darkfield, the edges of the frame target 400 may be illuminated. As such, the edge position may be determined based on the maximum derivative of the signal. The inner most edges may correspond to the top substrate (or current layer) and the outer most edges may be a combination of the bottom substrate (or previous layer) layer and the current feature. Thus, the CoM of the inner substrate may correspond to the position of the current layer and the CoM of the outer substrate may be an average position of the previous and current layer.

The method 800 may include a step 808 of generating an overlay measurement.

Referring to FIG. 1, the one or more processors 126 of a controller 124 may include any processing element known in the art. In this sense, the one or more processors 126 may include any microprocessor-type device configured to execute algorithms and/or instructions. In embodiments, the one or more processors 126 may consist of a desktop computer, mainframe computer system, workstation, image computer, parallel processor, or any other computer system (e.g., networked computer) configured to execute a program configured to operate the metrology system 100, as described throughout the present disclosure. It is further recognized that the term “processor” may be broadly defined to encompass any device having one or more processing elements, which execute program instructions from a non-transitory memory 128. Further, the steps described throughout the present disclosure may be carried out by a single controller 124 or, alternatively, multiple controllers. Additionally, the controller 124 may include one or more controllers housed in a common housing or within multiple housings. In this way, any controller or combination of controllers may be separately packaged as a module suitable for integration into metrology system 100.

The memory 128 may include any storage medium known in the art suitable for storing program instructions executable by the associated one or more processors 126. For example, the memory 128 may include a non-transitory memory medium. By way of another example, the memory 128 may include, but is not limited to, a read-only memory, a random-access memory, a magnetic or optical memory device (e.g., disk), a magnetic tape, a solid-state drive and the like. It is further noted that memory 128 may be housed in a common controller housing with the one or more processors 126. In embodiments, the memory 128 may be located remotely with respect to the physical location of the one or more processors 126 and controller 124. For instance, the one or more processors 126 of controller 124 may access a remote memory (e.g., server), accessible through a network (e.g., internet, intranet and the like). Therefore, the above description should not be interpreted as a limitation on the present invention but merely an illustration.

The described subject matter sometimes illustrates different components contained within, or connected with, other components. It is to be understood that such depicted architectures are merely exemplary, and that in fact many other architectures can be implemented which achieve the same functionality. In a conceptual sense, any arrangement of components to achieve the same functionality is effectively “associated” such that the desired functionality is achieved. Hence, any two components herein combined to achieve a particular functionality can be seen as “associated with” each other such that the desired functionality is achieved, irrespective of architectures or intermedial components. Likewise, any two components so associated can also be viewed as being “connected” or “coupled” to each other to achieve the desired functionality, and any two components capable of being so associated can also be viewed as being “couplable” to each other to achieve the desired functionality. Specific examples of couplable include but are not limited to physically interactable and/or physically interacting components and/or wirelessly interactable and/or wirelessly interacting components and/or logically interactable and/or logically interacting components.

It is believed that the present disclosure and many of its attendant advantages will be understood by the foregoing description, and it will be apparent that various changes may be made in the form, construction, and arrangement of the components without departing from the disclosed subject matter or without sacrificing all of its material advantages. The form described is merely explanatory, and it is the intention of the following claims to encompass and include such changes. Furthermore, it is to be understood that the invention is defined by the appended claims.

What is claimed:

1. An overlay metrology target comprising:
a first bonded substrate arranged on a first layer;
a second bonded substrate arranged on a second layer; and
a third bonded substrate arranged on a third layer,
wherein each bonded substrate includes one or more features embedded in a respective bonded substrate.

2. The overlay metrology target of claim 1, wherein the overlay metrology target is symmetrical.

3. The overlay metrology target of claim 2, wherein the overlay metrology target is a box-in-box target.

4. The overlay metrology target of claim 2, wherein the overlay metrology target is a circle-in-circle target.

5. The overlay metrology target of claim 2, wherein the overlay metrology target is an advanced imaging metrology target.

6. The overlay metrology target of claim 1, further comprising:
a side-by-side target.

7. The overlay metrology target of claim 6, wherein the one or more features comprise:
one or more frame targets, wherein the one or more frame targets are printed on each of the first bonded substrate, the second bonded substrate, and the third bonded substrate.

8. The overlay metrology target of claim 1, wherein the overlay metrology target is an image-based metrology target.

9. The overlay metrology target of claim 1, wherein the first bonded substrate includes a first bonded wafer, the second bonded substrate includes a second bonded wafer, and the third bonded substrate includes a third bonded wafer, wherein overlay between the first bonded wafer, the second bonded wafer, and the third bonded wafer is measured based on the one or more features on each bonded wafer.

10. The overlay metrology target of claim 1, wherein the first bonded substrate includes a bonded wafer, the second bonded substrate includes a first die, and the third bonded substrate includes a second die, wherein overlay between the bonded wafer and at least one of the first die or the second die is measured based on the one or more features on each bonded substrate, wherein overlay between the first die and the second die is measured based on the one or more features on each bonded substrate.

11. A metrology system comprising:
a light source configured to provide illumination;
a single objective lens configured to direct the illumination to an overlay metrology target on a sample and collect sample light from the overlay metrology target, wherein the overlay metrology target includes first bonded substrate arranged on a first layer, a second bonded substrate arranged on a second layer, and a third bonded substrate arranged on a third layer, wherein each bonded substrate includes one or more features embedded in a respective bonded substrate;
a detector configured to image the sample based on the sample light, wherein each feature of the one or more features of the overlay metrology target are within a field of view of the detector; and
a controller including one or more processors configured to execute program instructions causing the one or more processors to implement a metrology recipe by:
receiving an image of the overlay metrology target based on the metrology recipe; and
generating an overlay measurement based on the image.

12. The metrology system of claim 11, wherein the one or more processors are further configured to:
generate the image of the overlay metrology target using the detector.

13. The metrology system of claim 12, wherein the image is generated as a darkfield image.

14. The metrology system of claim 12, wherein the image is generated as a brightfield image.

15. The metrology system of claim 13, wherein the generating the overlay measurement based on the image comprises:
calculating a first center of symmetry for the first bonded substrate;
calculating an additional center of symmetry for at least one of the second bonded substrate or the third bonded substrate; and
comparing the first center of symmetry calculated and the additional center of symmetry calculated to determine the overlay measurement.

16. The metrology system of claim 14, wherein the generating the overlay measurement based on the image comprises:
calculating a first center of mass based on the first bonded substrate;
calculating an additional center of mass based on the second bonded substrate and the third bonded substrate; and
comparing the first center of mass calculated and the additional center of mass calculated to determine the overlay measurement.

17. The metrology system of claim 11, wherein the overlay metrology target is symmetrical.

18. The metrology system of claim 17, wherein the overlay metrology target is a box-in-box target.

19. The metrology system of claim 17, wherein the overlay metrology target is a circle-in-circle target.

20. The metrology system of claim 17, wherein the overlay metrology target is an advanced imaging metrology target.

21. The metrology system of claim 11, wherein the overlay metrology target further comprises:
a side-by-side target.

22. The metrology system of claim 21, wherein the one or more features comprise:
one or more frame targets, wherein the one or more frame targets are printed on each of the first bonded substrate, the second bonded substrate, and the third bonded substrate.

23. The metrology system of claim 11, wherein the overlay metrology target is an image-based metrology target.

24. The metrology system of claim 11, wherein the first bonded substrate includes a first bonded wafer, the second bonded substrate includes a second bonded wafer, and the third bonded substrate includes a third bonded wafer, wherein overlay between the first bonded wafer, the second bonded wafer, and the third bonded wafer is measured based on the one or more features on each bonded wafer.

25. The metrology system of claim 24, wherein the overlay measurement generated is between the first bonded wafer, the second bonded wafer, and the third bonded wafer.

26. The metrology system of claim 11, wherein the first bonded substrate includes a bonded wafer, the second bonded substrate includes a first die, and the third bonded substrate includes a second die, wherein overlay between the bonded wafer and at least one of the first die or the second die is measured based on the one or more features on each bonded substrate, wherein overlay between the first die and the second die is measured based on the one or more features on each bonded substrate.

27. The metrology system of claim 26, wherein the overlay measurement generated is between the bonded wafer, the first die, and the second die.

28. The metrology system of claim 26, wherein the overlay measurement generated is between the first die and the second die.

29. A metrology method comprising:
illuminating an overlay target on a sample with an objective lens with an illumination, wherein the sample comprises an overlay metrology target, wherein the overlay metrology target includes first bonded substrate arranged on a first layer, a second bonded substrate arranged on a second layer, and a third bonded substrate arranged on a third layer, wherein each bonded substrate includes one or more features embedded in a respective bonded substrate;
generating an image of the overlay metrology target with a detector; and
generating an overlay measurement based on the image.

30. The metrology method of claim 29, wherein generating the image of the overlay metrology target with the detector comprises:
generating the image as a darkfield image.

31. The metrology method of claim 29, wherein generating the image of the overlay metrology target with the detector comprises:
generating the image as a brightfield image.

32. The metrology method of claim 31, wherein the generating the overlay measurement based on the image comprises:
calculating a first center of symmetry for the first bonded substrate;
calculating an additional center of symmetry for at least one of the second bonded substrate or the third bonded substrate; and
comparing the first center of symmetry calculated and the additional center of symmetry calculated to determine the overlay measurement.

33. The metrology method of claim 30, wherein the generating the overlay measurement based on the image comprises:
calculating a first center of mass based on the first bonded substrate;
calculating an additional center of mass based on the second bonded substrate and the third bonded substrate; and
comparing the first center of mass calculated and the additional center of mass calculated to determine the overlay measurement.
